(19) United States
(12) Patent Application Publication
(10) Pub. No.: US 2021/0010130 A1
(43) Pub. Date: Jan. 14, 2021

(54) SUBSTRATE PROCESSING METHOD AND SUBSTRATE PROCESSING APPARATUS

(71) Applicant: TOKYO ELECTRON LIMITED, Tokyo (JP)

(72) Inventors: Kensaku NARUSHIMA, Nirasaki City (JP); Takanobu HOTTA, Nirasaki City (JP); Atsushi MATSUMOTO, Nirasaki City (JP); Takuya KAWAGUCHI, Nirasaki City (JP); Kouichi SEKIDO, Nirasaki City (JP)

(21) Appl. No.: 16/915,281

(22) Filed: Jun. 29, 2020

(30) Foreign Application Priority Data
Jul. 11, 2019 (JP) 2019-129548

(51) Int. Cl. C23C 14/54; C23C 14/24

(52) U.S. Cl. CPC C23C 14/544; C23C 14/24

(57) ABSTRACT

There is provided a substrate processing method in a substrate processing apparatus including a gas supplier that vaporizes a raw material in a raw material container and supplies a raw material gas together with a carrier gas, including: calibrating a relational expression between a flow rate of the carrier gas and a flow rate of the raw material gas; and processing a substrate in a processing container by controlling the flow rate of the carrier gas based on the relational expression and supplying the raw material gas into the processing container, wherein, in the calibrating the relational expression, the relational expression is derived by allowing the carrier gas to continuously flow.

### CROSS-REFERENCE TO RELATED APPLICATION

This application is based upon and claims the benefit of priority from Japanese Patent Application No. 2019-129548, filed on Jul. 11, 2019, the entire contents of which are incorporated herein by reference.

### TECHNICAL FIELD

The present disclosure relates to a substrate processing method and a substrate processing apparatus.

### BACKGROUND

In a semiconductor device manufacturing process, for example, a tungsten film is used for a gate electrode of a MOSFET, a word line of a DRAM, and the like.

Patent Document 1 discloses a film-forming apparatus including a gas supply device that vaporizes a raw material in a raw material container and supplies the raw material gas into a processing container together with a carrier gas.

### PRIOR ART DOCUMENT

### Patent Document

(Patent Document 1) Japanese Patent Application Publication No. 2018-145458

### SUMMARY

According to one embodiment of the present disclosure, there is provided a substrate processing method in a substrate processing apparatus including a gas supplier that vaporizes a raw material in a raw material container and supplies a raw material gas together with a carrier gas, including: calibrating a relational expression between a flow rate of the carrier gas and a flow rate of the raw material gas; and processing a substrate in a processing container by controlling the flow rate of the carrier gas based on the relational expression and supplying the raw material gas into the processing container, wherein, in the calibrating the relational expression, the relational expression is derived by allowing the carrier gas to continuously flow.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a film-forming apparatus according to the present embodiment.

FIG. 2 is an example of a flowchart for explaining an operation of the film-forming apparatus according to the present embodiment.

FIG. 3 is an example of a gas supply sequence in a film-forming step.

FIG. 4 is a graph for explaining the principle of calibration of a mass flow controller and measurement of a pickup amount of a precursor.

FIG. 5 is an example of a graph for explaining an operation in a calibration step.

FIGS. 6A and 6B are examples of a graph showing the relationship between a flow rate of a carrier gas and a pickup flow rate of a precursor.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. In each drawing, the same components may be denoted by like reference numerals, and duplicate description thereof may be omitted.

### [Film-Forming Apparatus]

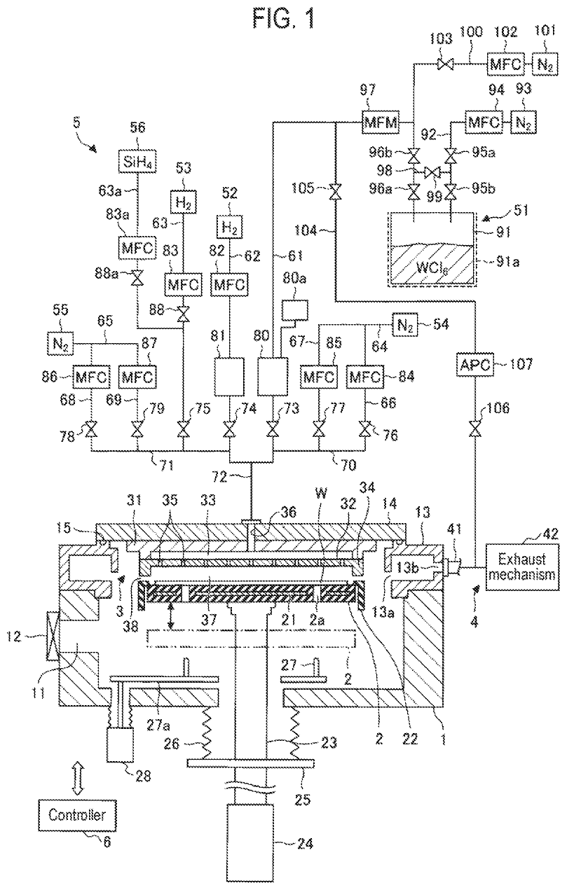

FIG. 1 is a schematic sectional view showing an example of a film-forming apparatus (substrate processing apparatus) according to the present embodiment. The film-forming apparatus according to the present embodiment is configured as an apparatus capable of performing film formation by an atomic layer deposition (ALD) method and film formation by a chemical vapor deposition (CVD) method.

The film-forming apparatus includes a processing container 1, a susceptor 2 for supporting a semiconductor wafer (hereinafter simply referred to as a wafer W) as a substrate in a horizontal posture in the processing container 1, a shower head 3 for supplying a processing gas into the processing container 1 in a showering manner, an exhaust part 4 for evacuating the interior of the processing container 1, a processing gas supplier 5 for supplying the processing gas to the shower head 3, and a controller 6.

The processing container 1 is made of a metal such as aluminum or the like and has a substantially cylindrical shape. A loading/unloading port 11 for loading or unloading the wafer W is formed on a sidewall of the processing container 1. The loading/unloading port 11 can be opened and closed by a gate valve 12. An annular exhaust duct 13 having a rectangular cross section is installed on the main body of the processing container 1. The exhaust duct 13 has a slit 13a formed along the inner circumferential surface of the exhaust duct 13. An exhaust port 13b is formed on the outer wall of the exhaust duct 13. A top wall 14 is installed on the upper surface of the exhaust duct 13 so as to close the upper opening of the processing container 1. The gap between the top wall 14 and the exhaust duct 13 is hermetically sealed by a seal ring 15.

The susceptor 2 has a disk shape having a size corresponding to the wafer W, and is supported by a support member 23. The susceptor 2 is made of a ceramic material such as aluminum nitride (AlN), or a metallic material such as aluminum, nickel-based alloy, and has a heater 21 embedded therein to heat the wafer W. The heater 21 is supplied with electric power from a heater power source (not shown) to generate heat. The output of the heater 21 is controlled by a temperature signal of a thermocouple (not shown) installed in the vicinity of the wafer mounting surface of the upper surface of the susceptor 2, whereby the wafer W is controlled to a predetermined temperature.

In the susceptor 2, there is provided a cover member 22 made of ceramics such as alumina so as to cover the outer peripheral region of the wafer mounting surface and the side surface of the susceptor 2.

The support member 23 that supports the susceptor 2 extends from the center of the bottom surface of the susceptor 2 toward below the processing container 1 while penetrating through the hole formed in the bottom wall of the processing container 1. The lower end of the support member 23 is connected to an elevating mechanism 24. The susceptor 2 can be moved up and down by the elevating mechanism 24 via the support member 23 between a processing position shown in FIG. 1 and a transfer position where the wafer can be transferred indicated by a two-dot chain line below the processing position. A flange portion 25 is attached to the support member 23 below the processing container 1. Between the bottom surface of the processing container 1 and the flange portion 25, there is provided a bellows 26 that isolates the atmosphere inside the processing container 1 from the ambient air and expands and contracts along with the up/down movement of the susceptor 2.

Three wafer support pins 27 (only two of which are shown) are installed near the bottom surface of the processing container 1 so as to protrude upward from a lifting plate 27a. The wafer support pins 27 can be moved up and down via the lifting plate 27a by a lifting mechanism 28 installed below the processing container 1. The wafer support pins 27 are inserted into through-holes 2a formed in the susceptor 2 at the transfer position, and can project and retract with respect to the upper surface of the susceptor 2. By raising and lowering the wafer support pins 27 in this manner, the wafer W is delivered between the wafer transfer mechanism (not shown) and the susceptor 2.

The shower head 3 is made of metal, and is installed so as to face the susceptor 2. The shower head 3 has a diameter substantially the same as that of the susceptor 2. The shower head 3 includes a main body 31 fixed to the top wall 14 of the processing container 1, and a shower plate 32 connected the lower portion of the main body 31. A gas diffusion space 33 is formed between the main body 31 and the shower plate 32. A gas introduction hole 36 is formed in the gas diffusion space 33 so as to penetrate the main body 31 and the center of the top wall 14 of the processing container 1. An annular protrusion 34 that protrudes downward is formed on the peripheral edge of the shower plate 32. Gas discharge holes 35 are formed on a flat surface inside the annular protrusion 34 of the shower plate 32.

In a state in which the susceptor 2 exists at the processing position, a processing space 37 is formed between the shower plate 32 and the susceptor 2, and the annular protrusion 34 and the upper surface of the cover member 22 of the susceptor 2 are close to each other to form an annular gap 38.

The exhaust part 4 includes an exhaust pipe 41 connected to the exhaust port 13b of the exhaust duct 13, and an exhaust mechanism 42 connected to the exhaust pipe 41 and including a vacuum pump, a pressure control valve and the like. At the time of processing, the gas in the processing container 1 reaches the exhaust duct 13 through the slit 13a and is exhausted from the exhaust duct 13 by the exhaust mechanism 42 of the exhaust part 4 through the exhaust pipe 41.

The processing gas supplier 5 includes a WCl₆ gas supplier 51, a first H₂ gas supply source 52, a second H₂ gas supply source 53, a first N₂ gas supply source 54, a second N₂ gas supply source 55, and a SiH₄ gas supply source 56. The WCl₆ gas supplier 51 supplies a WCl₆ gas as a metal chloride gas which is a raw material gas. The first H₂ gas supply source 52 supplies an H₂ gas as a reducing gas. The second H₂ gas supply source 53 supplies an H₂ gas as an additive reducing gas. The first N₂ gas supply source 54 and the second N₂ gas supply source 55 supply an N₂ gas which is a purge gas. The SiH₄ gas supply source 56 supplies a SiH₄ gas.

Furthermore, the processing gas supplier 5 includes a WCl₆ gas supply line 61, a first H₂ gas supply line 62, a second H₂ gas supply line 63, a first N₂ gas supply line 64, and a second N₂ gas supply line 65, and a SiH₄ gas supply line 63a. The WCl₆ gas supply line 61 is a line extending from the WCl₆ gas supplier 51. The first H₂ gas supply line 62 is a line extending from the first H₂ gas supply source 52. The second H₂ gas supply line 63 is a line extending from the second H₂ gas supply source 53. The first N₂ gas supply line 64 is a line that extends from the first N₂ gas supply source 54 and supplies an N₂ gas toward the WCl₆ gas supply line 61. The second N₂ gas supply line 65 is a line that extends from the second N₂ gas supply source 55 and supplies an N₂ gas toward the first H₂ gas supply line 62. The SiH₄ gas supply line 63a is a line extending from the SiH₄ gas supply source 56 and connected to the second H₂ gas supply line 63.

The first N₂ gas supply line 64 is branched into a first continuous N₂ gas supply line 66 that constantly supplies an N₂ gas during the film formation performed by an ALD method, and a first flush purge line 67 that supplies an N₂ gas only during a purge step. In addition, the second N₂ gas supply line 65 is branched into a second continuous N₂ gas supply line 68 that constantly supplies an N₂ gas during film formation performed by an ALD method, and a second flush purge line 69 that supplies an N₂ gas only during a purge step. The first continuous N₂ gas supply line 66 and the first flush purge line 67 are connected to a first connection line 70, and the first connection line 70 is connected to the WCl₆ gas supply line 61. Furthermore, the second H₂ gas supply line 63, the second continuous N₂ gas supply line 68 and the second flush purge line 69 are connected to a second connection line 71, and the second connection line 71 is connected to the first H₂ gas supply line 62. The WCl₆ gas supply line 61 and the first H₂ gas supply line 62 are joined to a joining pipe 72, and the joining pipe 72 is connected to the gas introduction hole 36 described above.

In the most downstream sides of the WCl₆ gas supply line 61, the first H₂ gas supply line 62, the second H₂ gas supply line 63, the first continuous N₂ gas supply line 66, the first flush purge line 67, the second continuous N₂ gas supply line 68 and the second flush purge line 69, there are provided opening/closing valves 73, 74, 75, 76, 77, 78 and 79, respectively, for switching the gas at the time of ALD. Furthermore, In the upstream sides of the opening/closing valves in the first H₂ gas supply line 62, the second H₂ gas supply line 63, the first continuous N₂ gas supply line 66, the first flush purge line 67, the second continuous N₂ gas supply line 68 and the second flush purge line 69, there are provided mass flow controllers 82, 83, 84, 85, 86 and 87, respectively, as flow rate controllers. The mass flow controller 83 is installed in the upstream side of a joining point of the SiH₄ gas supply line 63a in the second H₂ gas supply line 63. An opening/closing valve 88 is installed between the mass flow controller 83 and the joining point. Furthermore, in the SiH₄ gas supply line 63a, amass flow controller 83a and an opening/closing valve 88a are installed sequentially from the upstream side. Therefore, either or both of an H₂ gas and a SiH₄ gas can be supplied through the second H₂ gas supply line 63. In the WCl₆ gas supply line 61 and the first H₂ gas supply line 62, there are provided buffer tanks 80 and 81, respectively, so that necessary gases can be supplied in a short time. In the buffer tank 80, there is provided a pressure gauge 80a capable of detecting the pressure inside the buffer tank 80.

The WCl₆ gas supplier 51 includes a film-forming raw material tank 91 which is a raw material container for containing WCl₆. WCl₆ is a solid raw material that is solid at room temperature. A heater 91a is installed around the film-forming raw material tank 91 to heat the film-forming raw material in the film-forming raw material tank 91 to an appropriate temperature so as to sublimate WCl₆. The WCl₆ gas supply line 61 described above is inserted into the film-forming raw material tank 91 from above.

Further, the WCl₆ gas supplier 51 includes a carrier gas pipe 92 inserted into the film-forming raw material tank 91 from above, a carrier N₂ gas supply source 93 for supplying an N₂ gas, which is a carrier gas, into the carrier gas pipe 92, a mass flow controller 94 as a flow rate controller connected to the carrier gas pipe 92, opening/closing valves 95a and 95b on the downstream side of the mass flow controller 94, opening/closing valves 96a and 96b installed in the WCl₆ gas supply line 61 near the film-forming raw material tank 91, and a flow meter 97. In the carrier gas pipe 92, the opening/closing valve 95a is installed directly below the mass flow controller 94, and the opening/closing valve 95b is installed on the insertion end side of the carrier gas pipe 92. The opening/closing valves 96a and 96b and the flow meter 97 are arranged in the order of the opening/closing valve 96a, the opening/closing valve 96b and the flow meter 97 from the insertion end of the WCl₆ gas supply line 61.

A bypass pipe 98 is installed so as to connect a position between the opening/closing valve 95a and the opening/closing valve 95b of the carrier gas pipe 92 and a position between the opening/closing valve 96a and the opening/closing valve 96b of the WCl₆ gas supply line 61. An opening/closing valve 99 is installed in the bypass pipe 98. By closing the opening/closing valves 95b and 96a and opening the opening/closing valves 99, 95a and 96b, the N₂ gas supplied from the carrier N₂ gas supply source 93 is supplied to the WCl₆ gas supply line 61 through the carrier gas pipe 92 and the bypass pipe 98. As a result, the WCl₆ gas supply line 61 can be purged.

Furthermore, the downstream end of a dilution N₂ gas supply line 100 that supplies an N₂ gas as a dilution gas joins the upstream side of the flow meter 97 in the WCl₆ gas supply line 61. A dilution N₂ gas supply source 101, which is an N₂ gas supply source, is installed at an upstream end of the dilution N₂ gas supply line 100. A mass flow controller 102 and an opening/closing valve 103 are interposed and installed in the dilution N₂ gas supply line 100, sequentially from the upstream side.

One end of an evacuation line 104 is connected to a position on the downstream side of the flow meter 97 in the WCl₆ gas supply line 61, and the other end of the evacuation line 104 is connected to the exhaust pipe 41. An opening/closing valve 105 and an opening/closing valve 106 are installed in the evacuation line 104 at a position near the WCl₆ gas supply line 61 and a position near the exhaust pipe 41, respectively. A pressure control valve 107 is installed between the opening/closing valve 105 and the opening/closing valve 106. By opening the opening/closing valves 105, 106, 96a and 96b while maintaining the opening/closing valves 99, 95a and 95b closed, the interiors of the film-forming raw material tank 91 and the buffer tank 80 can be evacuated by the exhaust mechanism 42.

The controller 6 includes a process controller provided with a microprocessor (computer) that controls respective components, specifically, valves, power supply sources, heaters, pumps and the like, a user interface, and a memory part. The respective components of the film-forming apparatus are electrically connected to and controlled by the process controller. The user interface is connected to the process controller and includes a keyboard for an operator to input commands to manage the respective components of the film forming apparatus, a display that visualizes and displays the operating states of the respective components of the film forming apparatus, and the like. The memory part is also connected to the process controller. The memory part stores a control program for realizing various processes executed by the film-forming apparatus under the control of the process controller, a control program, i.e., process recipes, for causing each component of the film-forming apparatus to perform a predetermined process according process conditions, various databases, and the like. Furthermore, the memory part stores, for each process recipe, the pressure in the buffer tank 80 when the WCl₆ gas was supplied into the processing container 1 in the past to perform processing. The process recipes are stored in a non-transient storage medium (not shown) of the memory part. The storage medium may be a fixed one such as a hard disk, or may be a portable one such as a CDROM, a DVD, a semiconductor memory or the like. Furthermore, the recipes may be appropriately transmitted from another apparatus via, for example, a dedicated line. If necessary, a predetermined process recipe is called out from the memory part in response to an instruction or the like from the user interface and is caused to be executed by the process controller, so that a desired process is performed in the film-forming apparatus under the control of the process controller.

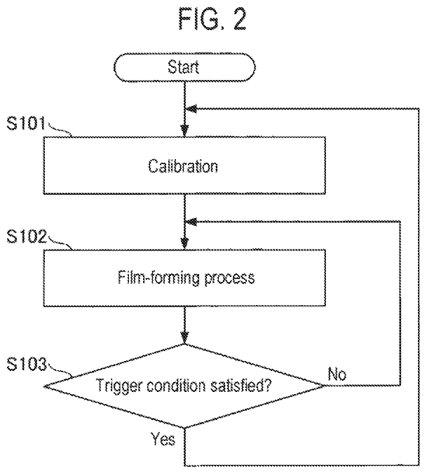

FIG. 2 is a flowchart for explaining the operation of the film-forming apparatus according to the present embodiment.

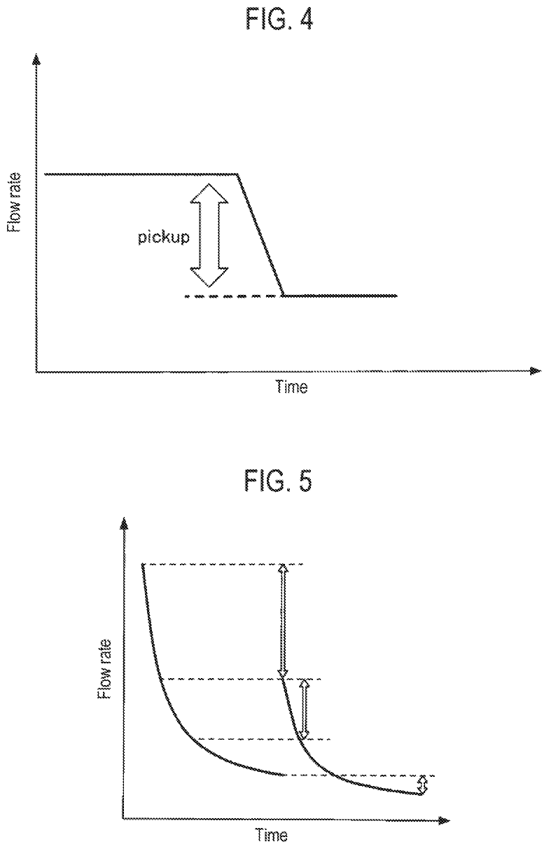

In step S101, the controller 6 performs a calibration step of calibrating a relational expression between a N₂ gas, which is a carrier gas supplied from the carrier N₂ gas supply source 93 to the film-forming raw material tank 91, and a flow rate of a precursor (raw material gas, i.e., WCl₆ gas), which is picked up from the film-forming raw material tank 91 by the carrier gas. The calibration of the relational expression in the calibration step will be described later with reference to FIG. 4.

In step S102, the controller 6 performs a film-forming process on a wafer W. For example, a tungsten film is formed on a wafer W having a base film formed on a surface of a silicon film having recesses such as trenches or holes.

First, the wafer W is loaded into the processing container 1 (loading step). Specifically, the gate valve 12 is opened with the susceptor 2 lowered to the transfer position, and the wafer W is loaded into the processing container 1 via the loading/unloading port 11 by the transfer device (not shown), and is mounted on the susceptor 2 heated to a predetermined temperature by the heater 21. Then, the susceptor 2 is raised to the processing position, and the interior of the processing container 1 is depressurized to a predetermined vacuum degree. Thereafter, the opening/closing valves 76 and 78 are opened, and the opening/closing valves 73, 74, 75, 77 and 79 are closed. Thus, the N₂ gas is supplied from the first N₂ gas supply source 54 and the second N₂ gas supply source 55 to the inside of the processing container 1 via the first continuous N₂ gas supply line 66 and the second continuous N₂ gas supply line 68 to increase the pressure in the processing container 1, and the temperature of the wafer W on the susceptor 2 is stabilized. At this time, a WCl₆ gas is supplied from the film-forming raw material tank 91 into the buffer tank 80, and the pressure inside the buffer tank 80 is maintained substantially constant. As the wafer W, a wafer having a base film formed on a surface of a silicon film having recesses such as trenches or holes may be used. Examples of the base film include titanium-based material films such as a TiN film, a TiSiN film, a Ti silicide film, a Ti film, a TiO film a TiAlN film and the like. Furthermore, as the base film, a tungsten-based compound film such as a WN film, a WSi, film, a WSiN film or the like may be used. By providing the base film on the surface of the silicon film, the tungsten film can be formed with good adhesion. In addition, the incubation time can be shortened.

Next, the interior of the buffer tank 80 is depressurized to a first pressure (depressurization step). Specifically, by opening the opening/closing valves 105, 106, 96a and 96b while keeping the opening/closing valves 99, 95a, 95b and 103 closed, the interior of the buffer tank 80 and the interior of the film-forming raw material tank 91 are evacuated via the evacuation line 104 by the exhaust mechanism 42. At this time, the interior of the buffer tank 80, the interior of the film-forming raw material tank 91 and the WCl₆ gas supply line 61 are depressurized to the first pressure. The first pressure may be a pressure in a vacuum state by the exhaust mechanism 42, or may be a predetermined pressure adjusted by the pressure control valve 107.

Next, the pressure in the buffer tank 80 is adjusted to a second pressure higher than the first pressure (adjustment step). Specifically, the opening/closing valves 105 and 106 are closed, and the opening/closing valves 95a, 95b and 103 are opened. As a result, the buffer tank 80 is filled with the N₂ gas supplied from the carrier N₂ gas supply source 93, the WCl₆ gas supplied from the film-forming raw material tank 91 and the N₂ gas supplied from the dilution N₂ gas supply line 100. Furthermore, the pressure in the buffer tank 80 may be adjusted to the second pressure by adjusting the opening degree of the pressure control valve 107. The second pressure is equal to the pressure in the buffer tank 80 when the WCl₆ gas was supplied into the processing container 1 to perform a process in the past, and may be stored in advance in the memory part, for example. The process performed in the past may be, for example, a process most recently performed with the same process recipe.

Next, a tungsten film is formed by using a WCl₆ gas, which is a metal chloride gas, and an H₂ gas, which is a reducing gas (film-forming step). The film-forming step is performed after the pressure in the buffer tank 80 is adjusted to the second pressure in the adjustment step.

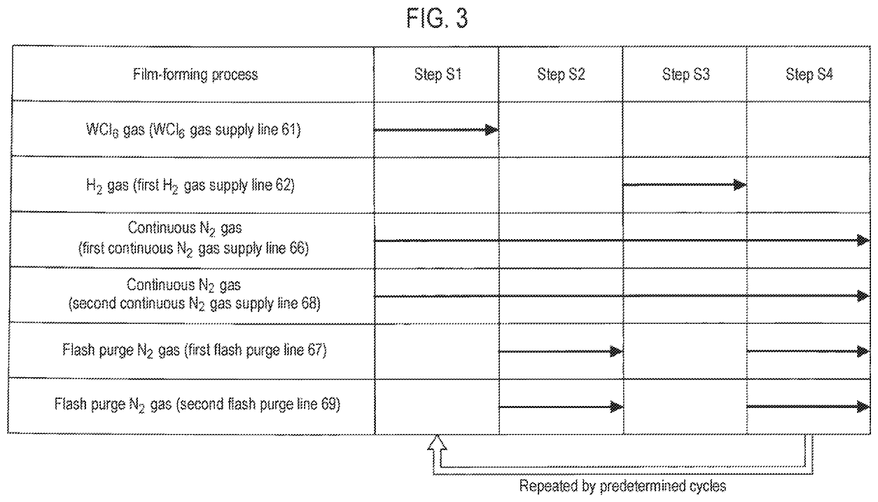

The film-forming step will now be further described. FIG. 3 is a view showing an example of a gas supply sequence in the film-forming step. A case in which a tungsten film is formed by an ALD method will be described by way of example.

Step S1 is a raw material gas supply step of supplying a WCl₆ gas to the processing space 37. In step S1, first, while opening the opening/closing valves 76 and 78, an N₂ gas is continuously supplied from the first N₂ gas supply source 54 and the second N₂ gas supply source 55 through the first continuous N₂ gas supply line 66 and the second continuous N₂ gas supply line 68. Furthermore, by opening the opening/closing valve 73, a WCl₆ gas is supplied from the WCl₆ gas supplier 51 to the processing space 37 in the processing container 1 through the WCl₆ gas supply line 61. At this time, the WCl₆ gas is once stored in the buffer tank 80 and then supplied into the processing container 1. The mass flow controller 94 is controlled based on the relational expression calibrated in step S101 (see FIG. 2). Furthermore, in step S1, an H₂ gas as an additive reducing gas may be supplied into the processing container 1 through the second H₂ gas supply line 63 extending from the second H₂ gas supply source 53. By supplying the reducing gas together with the WCl₆ gas in step S1, the supplied WCl₆ gas is activated, and a film formation reaction is easily generated in the subsequent step S3. Therefore, it is possible to maintain high step coverage and to increase the film thickness deposited per cycle, thereby increasing the film formation rate. The flow rate of the additive reducing gas may be set to a level at which a CVD reaction does not occur in step S1.

Step S2 is a purge step of purging a surplus WCl₆ gas and the like in the processing space 37. In step S2, the opening/closing valve 73 is closed and the supply of the WCl₆ gas is stopped while continuously supplying the N₂ gas through the first continuous N₂ gas supply line 66 and the second continuous N₂ gas supply line 68. Furthermore, the opening/closing valves 77 and 79 are opened, and the N₂ gas (flush purge N₂ gas) is also supplied from the first flush purge line 67 and the second flush purge line 69, whereby the surplus WCl₆ gas or the like in the processing space 37 is purged by the large flow rate of N₂ gas.

Step S3 is a reducing gas supply step of supplying an H₂ gas to the processing space 37. In step S3, the opening/closing valves 77 and 79 are closed to stop the supply of the N₂ gas from the first flush purge line 67 and the second flush purge line 69. Furthermore, the opening/closing valve 74 is opened in a state where the supply of the N₂ gas is continued via the first continuous N₂ gas supply line 66 and the second continuous N₂ gas supply line 68. As a result, an H₂ gas as a reducing gas is supplied to the processing space 37 from the first H₂ gas supply source 52 through the first H₂ gas supply line 62. At this time, the H₂ gas is once stored in the buffer tank 81 and then supplied into the processing container 1. In step S3, WCl₆ adsorbed on the wafer W is reduced. The flow rate of the H₂ gas at this time may be set to a level at which a reduction reaction is sufficiently generated.

Step S4 is a purge step of purging a surplus H₂ gas in the processing space 37. In step S4, the opening/closing valve 74 is closed to stop the supply of the H₂ gas from the first H₂ gas supply line 62 while continuously supplying the N₂ gas through the first continuous N₂ gas supply line 66 and the second continuous N₂ gas supply line 68. Furthermore, the opening/closing valves 77 and 79 are opened, and the N₂ gas (flush purge N₂ gas) is also supplied from the first flush purge line 67 and the second flush purge line 69, whereby the surplus H₂ gas in the processing space 37 is purged by the large flow rate of N₂ gas as in step S2.

A thin tungsten unit film is formed by performing the above steps S1 to S4 for one cycle in a short time, and a tungsten film having a desired film thickness is formed by repeating the cycle of these steps a plurality of times. The film thickness of the tungsten film at this time can be controlled by the number of repetitions of the above cycle.

When the film-forming step comes to an end, the wafer W is unloaded to the outside of the processing container 1 (unloading step). The unloading step may be performed by reversing the procedure of the loading step, and the description thereof is omitted. In the present embodiment, there has been described as an example the case where the loading step, the depressurization step, the adjustment step, the film-forming step and the unloading step are performed in the named order. However, the loading step and the depressurization step may be performed simultaneously.

Returning to FIG. 2, in step S103, the controller 6 determines whether a trigger condition is satisfied. The trigger condition is a condition for determining whether or not to perform the calibration step (S101) of calibrating the relational expression. If the trigger condition is not satisfied (if No in S103), the process of the controller 6 returns to step S102, and a film-forming process is performed on the next wafer W. If the trigger condition is satisfied (if Yes in S103), the process of the controller 6 proceeds to step S101 to calibrate the relational expression.

For example, the trigger condition is determined by determining whether the number of processed wafers W counted from the previous calibration exceeds a predetermined number. Furthermore, the trigger condition may be set for each FOUP. Moreover, the trigger condition may be determined by determining whether or not the film-forming apparatus is in an idle state. In addition, the trigger condition may be determined by determining whether the operation time of the film-forming apparatus counted from the previous calibration exceeds a predetermined threshold value. Furthermore, the trigger condition may be determined by determining whether or not the integrated film thickness of the tungsten film formed on the wafer W since the previous calibration exceeds a predetermined threshold value. In addition, the trigger condition may be determined by determining whether or not to change the recipe.

Next, the calibration step in step S101 will be further described with reference to FIGS. 4, 5, 6A and 6B.

FIG. 4 is a graph for explaining the principle of calibration of the mass flow controller 94 in the calibration step and measurement of the pickup amount of the raw material gas (precursor). In FIG. 4, the horizontal axis represents the time, and the vertical axis represents the flow rate detected by the flow meter 97.

First, an automatic continuous flow is performed in which a carrier gas is continuously supplied to pick up a precursor. Specifically, the controller 6 closes the opening/closing valve 99 and opens the opening/closing valves 95a. 95b, 96a, 96b and 73. As a result, the carrier gas supplied from the carrier N₂ gas supply source 93 is supplied to the film-forming raw material tank 91 through the mass flow controller 94. The sublimed raw material gas in the film-forming raw material tank 91 is picked up by the carrier gas. The raw material gas and the carrier gas are supplied to the processing container 1 through the flow meter 97 and exhausted by the exhaust part 4. At this time, the flow rate of the raw material gas and the carrier gas is measured by the flow meter 97.

Next, a bypass flow is performed in which a carrier gas is caused to continuously flow by bypassing the film-forming raw material tank 91. Specifically, the controller 6 closes the opening/closing valves 95b and 96a and opens the opening/closing valves 95a. 99, 96b and 73. As a result, the carrier gas supplied from the carrier N₂ gas supply source 93 is supplied to the processing container 1 through the mass flow controller 94, the bypass pipe 98 and the flow meter 97, and is exhausted by the exhaust part 4. At this time, the flow rate of the carrier gas is measured by the flow meter 97.

The controller 6 calibrates the mass flow controller 94 based on the control value of the mass flow controller 94 (e.g., the valve opening degree) during the bypass flow and the detection value of the flow meter 97. In addition, the controller 6 measures the flow rate of the picked-up precursor based on a difference (indicated by a white arrow in FIG. 4) between the detection value of the flow meter 97 during the automatic continuous flow and the flow rate of the calibrated mass flow controller 94. During the automatic continuous flow and the bypass flow, the opening/closing valve 73 is always opened, the gas is not stored in the buffer tank 80, and the gas continuously flows to the exhaust part 4. Therefore, the detection value of the flow meter 97 does not fluctuate, and the flow rate can be measured accurately.

FIG. 5 is an example of a graph for explaining the operation in the calibration step. In FIG. 5, the horizontal axis represents the time and the vertical axis represents the flow rate detected by the flow meter 97.

In the calibration step, the controller 6 maintains the respective opening/closing valves in an automatic continuous flow state and controls the mass flow controller 94 to continuously supply the carrier gas to pick up the precursor. At this time, the flow rate of the carrier gas controlled by the mass flow controller 94 is measured by the flow meter 97 while changing the flow rate from a large flow rate (a first flow rate) to a small flow rate (a second flow rate).

Next, the controller 6 maintains the respective opening/closing valves in a bypass flow state and controls the mass flow controller 94 to continuously supply the carrier gas. At this time, the flow rate of the carrier gas controlled by the mass flow controller 94 is measured by the flow meter 97 while changing the flow rate from a large flow rate to a small flow rate.

The controller 6 calibrates the relationship between the control value of the mass flow controller 94 (e.g., the valve opening degree) and the flow rate of the carrier gas based on the relationship between the detection value of the flow meter 97 during the bypass flow and the control value of the mass flow controller 94 (e.g., the valve opening degree) at each time point. In addition, the pickup flow rate of the precursor is obtained from a difference (indicated by a white arrow in FIG. 5) between the detection value of the flow meter 97 during the automatic continuous flow and the detection value of the flow meter 97 during the bypass flow at a certain control value of the mass flow controller 94 (e.g., the valve opening degree). Thus, it is possible to obtain the relationship between the flow rate of the carrier gas and the pickup flow rate of the precursor.

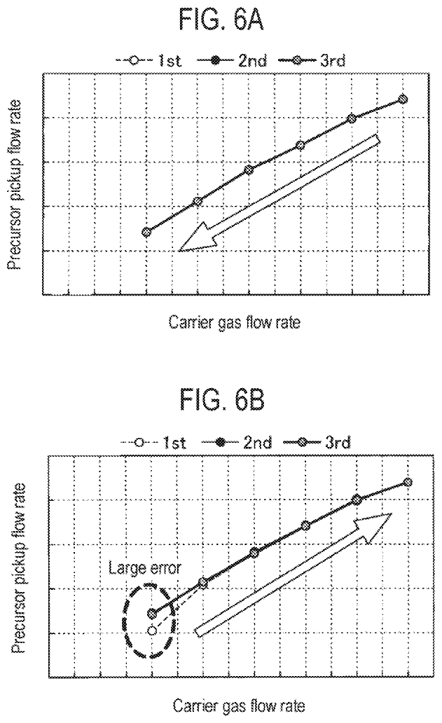

FIGS. 6A and 6B are examples of a graph showing the relationship between the flow rate of the carrier gas and the pickup flow rate of the precursor. The horizontal axis represents the flow rate of the carrier gas, and the vertical axis represents the pickup flow rate of the precursor.

FIG. 6A shows a case where the flow rate of the carrier gas is controlled so as to be changed from a large flow rate to a small flow rate. FIG. 6B shows a case where the flow rate of the carrier gas is controlled so as to be changed from a small flow rate to a large flow rate. Furthermore, as shown in FIGS. 6A and 6B, the measurement during the automatic continuous flow and the bypass flow shown in FIG. 5 was conducted three times for each of the automatic continuous flow and the bypass flow.

As shown in FIG. 6B, when the flow rate of the carrier gas is changed from the small flow rate to the large flow rate, the measurement value at the first measurement in the small flow rates has a large error as compared with the measurement values at the second and subsequent measurements in the small flow rates.

On the other hand, as shown in FIG. 6A, when the flow rate of the carrier gas is changed from the large flow rate to the small flow rate, almost no error occurred at the first to third measurements.

At the start of the measurement, the state of the WCl₆ gas supply line 61 (e.g., the temperature of the flow meter 97, the temperature of each pipe, the pressure in each pipe, etc.) is not steady and disturbs the measurement value of the flow meter 97. Thus, errors easily occur. In the configuration in which the measurement is started from the small flow rate as shown in FIG. 6B, the influence of the initial state of the WCl₆ gas supply line 61 cannot be sufficiently eliminated. As compared with the second and subsequent measurements at which the state of the WCl₆ gas supply line 61 becomes stable, a large error occurs in the measurement value at the start of the measurement. On the other hand, in the configuration in which the measurement is started from the large flow rate as shown in FIG. 6A, the state of the WCl₆ gas supply line 61 can be quickly brought into a steady state. Therefore, it is possible to reduce the error in the measurement value at the start of the measurement.

Although not shown, by first performing the automatic continuous flow and then performing the bypass flow, it is possible to suppress occurrence of an error as compared with the case where the bypass flow is performed first and the automatic continuous flow is performed later. When the bypass flow is performed first and the automatic continuous flow is performed later, the gas heated by the heater 91a in the subsequent automatic continuous flow is supplied to the flow meter 97. Therefore, a temperature difference may exist between the temperature of the flow meter 97 during the bypass flow and the temperature of the flow meter 97 during the automatic continuous flow, which may cause a measurement error in the flow meter 97. On the other hand, when the automatic continuous flow is performed first and the bypass flow is performed later, the gas heated by the heater 91a in the previous automatic continuous flow is supplied to the flow meter 97. Therefore, the temperature difference between the temperature of the flow meter 97 during the automatic continuous flow and the temperature of the flow meter 97 during the bypass flow can be reduced, which makes it possible to reduce the measurement error of the flow meter 97.

As described above, the relationship between the flow rate of the carrier gas and the pickup flow rate of the precursor can be accurately measured. The controller 6 derives (calibrates) a relational expression based on the relationship of the measured flow rates. For example, the relational expression is derived by the least square method. Then, in the film-forming process in step S102 (see FIG. 2), the supply of the raw material gas is controlled using the relational expression obtained in step S101.

As described above, according to the film-forming apparatus of the present embodiment, the supply amount of the raw material gas (precursor) in the film-forming process can be controlled appropriately. Thus, for example, the film thickness between the wafers W can be made uniform, and the film formation reproducibility can be improved.

Since the calibration step is performed when the trigger condition is satisfied, it is possible to reduce the raw material used for the calibration as compared with a case where the calibration is performed for each wafer (see, e.g., Patent Document 1). Furthermore, when the calibration is performed for each individual wafer, there is a possibility that a variation in control may be generated due to the accuracy of the flow meter 97 and the film formation characteristics between the respective wafers W may vary. On the other hand, according to the film-forming apparatus of the present embodiment, the mass flow controller 94 is controlled based on the calibrated relational expression until the following trigger condition is satisfied. As a result, the variation in control due to the accuracy of the flow meter 97 can be suppressed, the film thickness between the wafers W can be made uniform, and the film formation reproducibility can be improved.

Although the film-forming apparatus according to the present embodiment has been described above, the present disclosure is not limited to the above-described embodiment and the like. Various modifications and improvements may be made within the scope of the gist of the present disclosure described in the claims.

Although the gas is supplied to the processing container 1 in the calibration step, the present disclosure is not limited thereto. The gas may be supplied to the evacuation line 104. Furthermore, the gas may be supplied to both the processing container 1 and the evacuation line 104.

Although the single-wafer type film-forming apparatus has been described as an example, the present disclosure is not limited thereto. The present disclosure may be applied to film formation in a multi-wafer film-forming apparatus. In addition, the present disclosure may be applied to film formation in a batch type film-forming apparatus.

Although the film-forming apparatus has been described as an apparatus that performs film formation by the ALD method, the present disclosure is not limited thereto and may be applied to a film-forming apparatus that performs film formation by a CVD method.

Furthermore. WCl₆ has been described as an example of the raw material stored in the film-forming raw material tank 91. However, the raw material is not limited thereto and may be other solid raw materials. Furthermore, the raw material is not limited to the solid raw materials. The present disclosure may be applied to a case where the relational expression between the carrier gas and the raw material gas is calibrated in the film-forming apparatus using a liquid raw material.

Furthermore, although an example was described where the film-forming apparatus performs the flow rate measurement during the bypass flow after the flow rate measurement during the automatic continuous flow, the present disclosure is not limited thereto. When changing the flow rate of the carrier gas from the large flow rate to the small flow rate, if the flow rate of the carrier gas remains the same, the flow rate measurement during the bypass flow may be sequentially performed after the flow rate measurement during the automatic continuous flow. Specifically, the controller 6 controls the mass flow controller 94 to change the flow rate of the carrier gas from a large flow rate to a small flow rate on a stage-by-stage basis. Furthermore, when the flow rate of the carrier gas at each stage is the same, the controller 6 performs flow rate measurement during the automatic continuous flow, and performs flow rate measurement during the bypass flow by switching the opening and closing of the opening/closing valves 95a, 95b, 96a, 96b and 99 while maintaining the control value of the mass flow controller 94 (e.g., the valve opening degree). This makes it possible to accurately measure the relationship between the flow rate of the carrier gas and the pickup flow rate of the precursor. In addition, it is possible to derive (calibrate) a relational expression based on the measured flow rate relationship.

According to the present disclosure in some embodiments, it is possible to provide a substrate processing method and a substrate processing apparatus capable of improving film formation reproducibility.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method in a substrate processing apparatus including a gas supplier that vaporizes a raw material in a raw material container and supplies a raw material gas together with a carrier gas, the method comprising:
calibrating a relational expression between a flow rate of the carrier gas and a flow rate of the raw material gas; and
processing a substrate in a processing container by controlling the flow rate of the carrier gas based on the relational expression and supplying the raw material gas into the processing container,
wherein, in the calibrating the relational expression, the relational expression is derived by allowing the carrier gas to continuously flow.

2. The method of claim 1, wherein, in the calibrating the relational expression, the flow rate of the carrier gas is changed from a first flow rate to a second flow rate, wherein the first flow rate is greater than the second flow rate.

3. The method of claim 2, wherein the calibrating the relational expression further comprises:
detecting the flow rate of the carrier gas and the flow rate of the raw material gas by supplying the carrier gas into the raw material container; and
detecting the flow rate of the carrier gas by bypassing the raw material container.

4. The method of claim 3, wherein in the calibrating the relational expression, the detecting the flow rate of the carrier gas and the flow rate of the raw material gas by supplying the carrier gas into the raw material container is performed first, and then the detecting the flow rate of the carrier gas by bypassing the raw material container is performed later.

5. The method of claim 4, further comprising:
recalibrating the relational expression between the flow rate of the carrier gas and the flow rate of the raw material gas, when a predetermined trigger condition is satisfied.

6. The method of claim 1, wherein the calibrating the relational expression further comprises:
detecting the flow rate of the carrier gas and the flow rate of the raw material gas by supplying the carrier gas into the raw material container; and
detecting the flow rate of the carrier gas by bypassing the raw material container.

7. The method of claim 1, further comprising:
recalibrating the relational expression between the flow rate of the carrier gas and the flow rate of the raw material gas, when a predetermined trigger condition is satisfied.

8. A substrate processing apparatus, comprising:
a processing container;
a mounting table disposed in the processing container and configured to mount a substrate;
a gas supplier configured to vaporize a raw material in a raw material container and supply a raw material gas together with a carrier gas; and
a controller,
wherein the controller is configured to execute:
calibrating a relational expression between a flow rate of the carrier gas and a flow rate of the raw material gas; and
processing the substrate by controlling the flow rate of the carrier gas based on the relational expression and supplying the raw material gas into the processing container,
wherein, in the calibrating the relational expression, the relational expression is derived by allowing the carrier gas to continuously flow.
